(19) United States
(12) Patent Application Publication
(10) Pub. No.: US 2021/0391210 A1
(43) Pub. Date: Dec. 16, 2021

(54) METHOD FOR MANUFACTURING A CAPACITOR

(71) Applicant: HUA HONG SEMICONDUCTOR (WUXI) LIMITED, Wuxi (CN)

(72) Inventors: Junwen LIU, Wuxi (CN); Hualun CHEN, Wuxi (CN)

(73) Assignee: HUA HONG SEMICONDUCTOR (WUXI) LIMITED, Wuxi (CN)

(21) Appl. No.: 17/092,562

(22) Filed: Nov. 9, 2020

(30) Foreign Application Priority Data
Jun. 15, 2020 (CN) 202010541238.0

(51) Int. Cl. H01L 21/768; H01L 21/8234; H01L 49/02

(52) U.S. Cl. CPC H01L 21/7687; H01L 21/823475; H01L 21/32053; H01L 21/7685; H01L 28/60

(57) ABSTRACT

A method for manufacturing a capacitor includes: forming a polysilicon layer on a substrate; forming a polysilicon structure by etching the polysilicon layer, wherein the polysilicon structure comprises a lower electrode plate of the capacitor; forming sidewalls on two sides of the polysilicon structure; depositing a dielectric layer and a conductive layer sequentially; performing a photolithography process to define salicide block layer patterns and upper electrode plate patterns of the capacitor; forming a salicide block layer, and an upper electrode plate and a dielectric layer of the capacitor, by sequentially etching the conductive layer and the dielectric layer, according to the salicide block layer patterns and the upper electrode plate patterns of the capacitor; and forming salicides.

### CROSS-REFERENCES TO RELATED APPLICATIONS

This application claims the priority to Chinese patent application No. 202010541238.0 filed at CNIPA on Jun. 15, 2020, and entitled “METHOD FOR MANUFACTURING A CAPACITOR”, the disclosure of which is incorporated herein by reference in entirety.

### TECHNICAL FIELD

The present disclosure relates to the field of semiconductor manufacturing, in particular to a method for manufacturing a capacitor.

### BACKGROUND

With the development of semiconductor manufacturing technologies, capacitors in semiconductor devices include metal insulator metal (MIM) capacitors, poly insulator poly (PIP) capacitors, and metal oxide metal (MOM) capacitors, etc., wherein the PIP capacitors are widely applied due to relatively simple manufacturing thereof.

The upper and lower electrode plates of a PIP capacitor both are polysilicon, and there is an insulation layer between the upper and lower electrode plates. In the traditional manufacturing process of the PIP capacitor, a separate photolithography mask is required for defining the upper electrode plate of the capacitor, that is, integrating the PIP capacitor into a device requires additional photolithography process and etching process, thereby increasing the manufacturing cost.

However, in the current technological process, manufacturing of the PIP capacitor requires a plurality of additional photolithography processes, including polysilicon layer deposition, an additional photolithography step, and an additional photolithography mask, thereby increasing the manufacturing cost.

### BRIEF SUMMARY

According to some embodiments in this application, a method for manufacturing a capacitor is disclosed in the following steps: forming a polysilicon layer on a substrate; forming a polysilicon structure by etching the polysilicon layer, wherein the polysilicon structure comprises a lower electrode plate of the capacitor; forming sidewalls on two sides of the polysilicon structure; depositing a dielectric layer and a conductive layer sequentially; performing a photolithography process to define salicide block layer patterns and upper electrode plate patterns of the capacitor; forming a salicide block layer, and an upper electrode plate and a dielectric layer of the capacitor, by sequentially etching the conductive layer and the dielectric layer, according to the salicide block layer patterns and the upper electrode plate patterns of the capacitor; and forming silicides.

### BRIEF DESCRIPTION OF THE DRAWINGS

FIG. 1 is a flowchart of a method for manufacturing a capacitor, according to one embodiment of the present application.

FIG. 2 is the device cross sectional view of the capacitor, according to one embodiment of the present application.

FIG. 2A is the another device cross sectional view of the capacitor, according to one embodiment of the present application.

FIG. 3 is a device cross sectional view, according to one embodiment of the present application.

FIG. 4 is a device cross sectional view, according to one embodiment of the present application.

FIG. 5 is a device cross sectional view, according to one embodiment of the present application.

FIG. 6 is a device cross sectional view, according to one embodiment of the present application.

FIG. 7 is a device cross sectional view, according to one embodiment of the present application.

### DETAILED DESCRIPTION OF THE DISCLOSURE

The technical solutions in this application will be clearly and completely described below with reference to the drawings. Obviously, the described embodiments are part of the embodiments of the application, instead of all them. Based on the embodiments in the present application, all other embodiments obtained by one skilled in the art without contributing any inventive labor shall fall into the protection scope of the present application.

In the description of this application, it should be noted that the orientation or positional relationship indicated by the terms “center”, “upper”, “lower”, “left”, “right”, “vertical”, “horizontal”, “inside”, “outside”, or the like is based on the orientation or positional relationship shown in the drawings, is only for the convenience of describing this application and simplified description, and does not indicate or imply that the indicated device or element must have a specific orientation or be configured and operated in a specific orientation. Therefore, the orientation or positional relationship should not to be construed as limitations on the present application. In addition, the terms “first,” “second,” and “third” are used for descriptive purposes only, and should not be construed to indicate or imply relative importance.

In the description of this application, it should be noted that the terms “installation”, “connected”, and “connection” should be understood in a broad sense, unless explicitly stated and defined otherwise, for example, they may be fixed connection or removable connection, or integral connection; can be mechanical or electrical connection; can be direct connection, or indirect connection through an intermediate medium, or the internal communication of two elements, and can be wireless or wired connection. For those of ordinary skill in the art, the specific meanings of the above terms in this application can be understood in specific situations.

In addition, the technical features involved in the different implementations of the present application described below can be combined with each other as long as they do not conflict with each other.

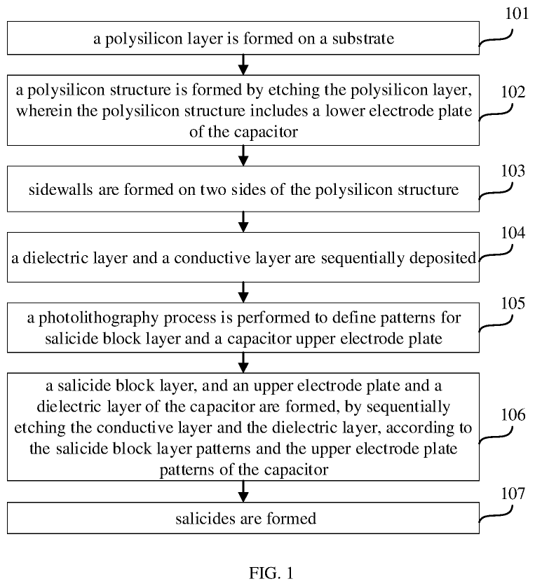

FIG. 1 illustrates a flowchart of a method for manufacturing a capacitor, according to one embodiment of the present application, including the following steps:

In step 101, a polysilicon layer is formed on a substrate.

A layer of polysilicon is deposited on the substrate.

In step 102, a polysilicon structure is formed by etching the polysilicon layer, wherein the polysilicon structure includes a lower electrode plate of the capacitor.

A plurality of semiconductor devices of different types may be manufactured on the same substrate. Polysilicon structures of the different semiconductor devices can be formed in the same etch process, for example, a polysilicon gate of a CMOS device and a lower electrode plate of a capacitor are formed in the same etch process.

A photolithography process is performed to define patterns for the polysilicon structure, and a etch process is performed to form the polysilicon structure.

The polysilicon structure includes the lower electrode plate of the capacitor.

In step 103, sidewalls are formed on two sides of the polysilicon structure.

A material used to form the sidewall is deposited, etch back is performed, and the etch process stops when the polysilicon layer is exposed, to form the sidewall.

In step 104, a dielectric layer and a conductive layer are sequentially deposited.

The dielectric layer is deposited, and the conductive layer is deposited on the dielectric layer.

The material of the conductive layer is a conductive material, such as titanium nitride, polysilicon, metal, or a conductive alloy.

Since the dielectric layer is non-conductive, the stacked dielectric layer and conductive layer can be used as a salicide block layer to prevent formation of silicide in a certain region.

In step 105, a photolithography process is performed to define patterns for salicide block layer and a capacitor upper electrode plate.

The capacitor comprises of the lower electrode plate, a dielectric layer, and an upper electrode plate. The deposited dielectric layer also used to form the dielectric layer of the capacitor, and the deposited conductive layer also used to form the upper electrode plate of the capacitor.

Since the stacked dielectric layer and conductive layer can be used to form the salicide block layer as well as the capacitor, photolithography of the salicide block layer and photolithography of the capacitor can be performed with the same mask, that is, the photolithography of the salicide block layer and the photolithography of the capacitor are performed at the same time, and the etch process of the salicide block layer and the etch process of the capacitor are performed at the same time, without additional photolithography and etching process to manufacture the capacitor.

In step 106, a salicide block layer, and an upper electrode plate and a dielectric layer of the capacitor are formed, by sequentially etching the conductive layer and the dielectric layer, according to the salicide block layer patterns and the upper electrode plate patterns of the capacitor.

The etched conductive layer completely covers the etched dielectric layer. The dielectric layer and the conductive layer in a capacitor region form the dielectric layer and the upper electrode plate of the capacitor; and the dielectric layer and the conductive layer outside the capacitor region together form the salicide block layer.

In step 107, salicides are formed.

A layer of metal, such as Ti, Co, or Ni, is formed on the substrate by means of sputtering; then, rapid thermal annealing processing is performed, such that the metal layer formed by means of sputtering reacts with the polysilicon below the metal layer to form the salicides.

It should be noted that if the material of the conductive layer is polysilicon, the salicides are also formed on the top of the etched conductive layer; and if the material of the conductive layer is a conductive material other than polysilicon, a metal material formed on the top of the conductive layer during the processing of forming the salicides do not need to be removed.

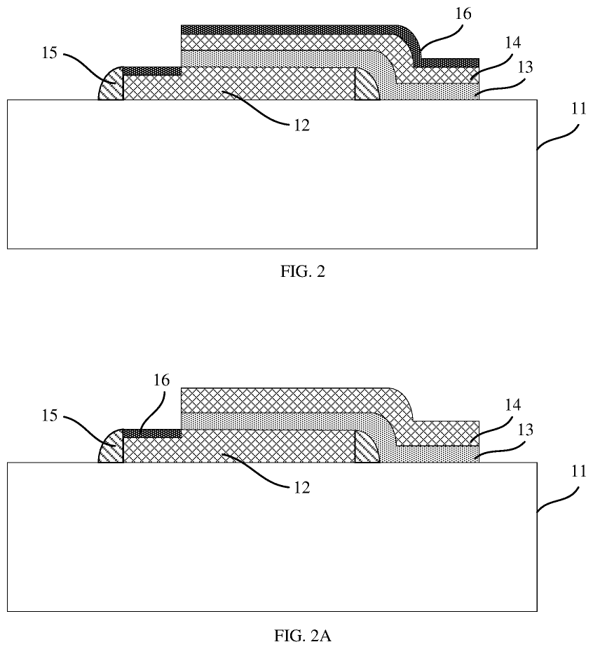

FIG. 2 illustrates the device cross sectional view of the capacitor, according to one embodiment of the present application. The capacitor is formed on the substrate 11. The capacitor comprises the lower electrode plate 12, the dielectric layer 13, and the upper electrode plate 14, wherein the sidewalls 15 are formed on two sides of the lower electrode plate 12, the upper electrode plate 14 completely covers the dielectric layer 13, the dielectric layer 13 is located above the lower electrode plate 12, the dielectric layer 13 covers a portion of the surface of the lower electrode plate 12, the dielectric layer 13 extends from the surface of the lower electrode plate 12 to the surface of the substrate 11, and the dielectric layer 13 covers the sidewall on one side of the lower electrode plate 12. Since the material of the lower electrode plate is polysilicon, the salicide 16 is also formed on the top of the lower electrode plate 12 not covered with the dielectric layer 13.

In an example, if the material of the conductive layer is polysilicon, the material of the upper electrode plate 14 of the capacitor is polysilicon, and the salicide 16 is also formed on the top of the upper electrode plate 14, referring to FIG. 2.

In another example, if the conductive layer material is titanium nitride, the material of the upper electrode plate 14 of the capacitor is titanium nitride, and the salicide 16 is not formed on the top of the upper electrode plate 14, referring to FIG. 2A.

In summary, the conductive layer and the dielectric layer are used as the salicide block layer, combining the etch of the salicide block layer and the etch of the upper electrode plate and the dielectric layer of the capacitor, the current problem of a high manufacturing cost in capacitor manufacture is solved.

The benefit of this technique includes: optimizing the manufacture process of an integrated capacitor and reducing the manufacture cost.

If a CMOS device and a capacitor are be manufactured on the same substrate, according to one embodiment of the present application, a method for manufacturing a capacitor includes the following steps:

In step 201, active regions are defined on a substrate, and field oxide layers are formed in regions outside the active regions.

The field oxide layers are formed on the substrate, the active regions are defined by the field oxide layers.

In step 202, a polysilicon layer is formed on the substrate.

The gate oxide layer is formed on the surface of the substrate.

A layer of polysilicon is deposited on the surface of the substrate.

In step 203, a photolithography process is performed to define the regions for a gate of the CMOS device and a lower electrode plate.

Photoresist is spin-coated on the surface of the substrate, and a mask is used for exposure, wherein the mask includes a gate pattern of the CMOS device and a lower electrode plate pattern of the capacitor; and development is performed to copy the gate pattern of the CMOS device and the lower electrode plate pattern of the capacitor into the photoresist.

In step 204, a process of etching the polysilicon layer is performed to form a polysilicon structure, the polysilicon structure includes the gate of the CMOS device and the lower electrode plate of the capacitor.

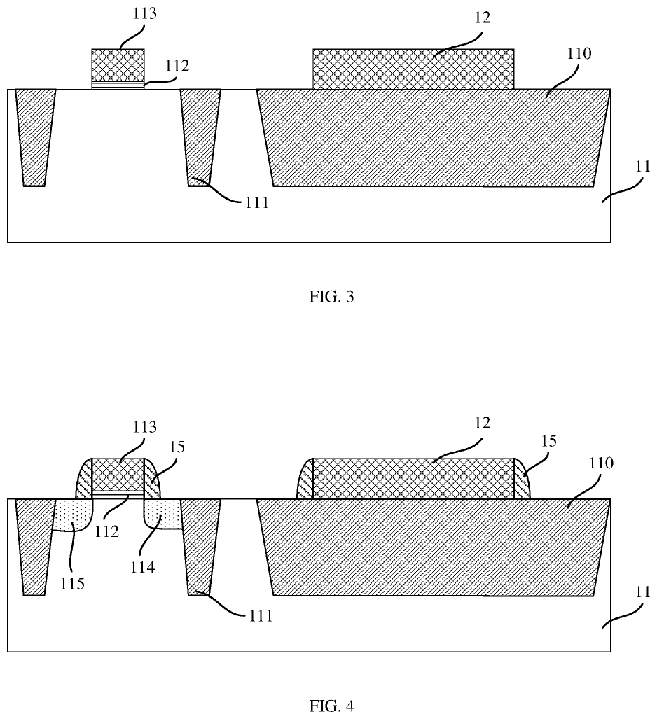

FIG. 3 illustrates the device cross sectional view, according to one embodiment of the present application.

The active regions are defined on the substrate 11 by shallow trench isolation 111, the gate 113 of the CMOS device is on the gate oxide layer 112 in the active region, and the lower electrode plate 12 of the capacitor is on the field oxide layer 110, referring to FIG. 3.

After the etch process is completed, the photoresist above the polysilicon layer is removed.

In step 205, lightly doped drain implantation of the CMOS device is performed.

According to the positions of a source region and a drain region of the CMOS device, the lightly doped drain implantation is performed on two sides of the gate of the CMOS device.

In step 206, sidewalls are formed on two sides of the gate of the CMOS device and on two sides of the lower electrode plate of the capacitor.

In one example, the material of the gate sidewalls are an oxide layer and a silicon nitride layer; an oxide layer is grown on the outside of the polysilicon gate and the lower electrode plate of the capacitor, then a silicon nitride layer is deposited and etched back, and the etch process stops when the polysilicon layer is exposed, to form the sidewalls of the CMOS device and the sidewalls of capacitor lower electrode plate.

In step 207, a source region and a drain region of the CMOS device are formed.

According to the positions of the source region and the drain region of the CMOS device, ion implantation and anneal are performed separately to form the source region and the drain region of the CMOS device.

FIG. 4 is the device cross sectional view, according to one embodiment of the present application.

Referring to FIG. 4, the sidewalls 15 are formed on two sides of the gate 113 of the CMOS device and on two sides of the lower electrode plate 12 of the capacitor, respectively, and the drain region 114 and the source region 115 of the CMOS device are formed in the substrate 11.

In step 208, a dielectric layer and a conductive layer are sequentially deposited.

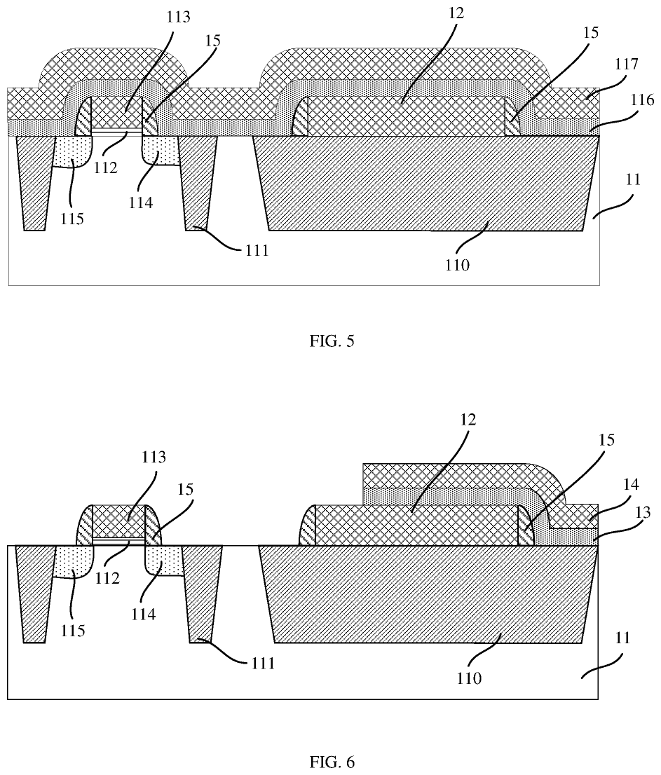

In an example, the material of the conductive layer is polysilicon, referring to FIG. 5, the dielectric layer 116 is deposited on the substrate, and the conductive layer 117 is deposited on the dielectric layer 116.

The deposited dielectric layer 116 and conductive layer 117 are to be silicide block layer. The deposited dielectric layer 116 is also used to form a dielectric layer of the capacitor, and the deposited conductive layer 117 is also used to form an upper electrode plate of the capacitor.

In step 209, a photolithography process is performed to define patterns for salicide block layer and a capacitor upper electrode plate.

Photoresist is spin-coated on the surface of the substrate, and a mask is used for exposure, wherein the mask includes the salicide block layer pattern and the capacitor upper electrode plate pattern; and development is performed to copy the salicide block layer pattern and the capacitor upper electrode plate pattern into the photoresist.

In step 210, a salicide block layer, and an upper electrode plate and a dielectric layer of the capacitor are formed, by sequentially etching the conductive layer and the dielectric layer, according to the salicide block layer patterns and the upper electrode plate patterns of the capacitor.

According to the salicide block layer patterns and the capacitor upper electrode plate patterns, the conductive layer is etched first, and then the dielectric layer is etched, wherein the etched conductive layer completely covers the dielectric layer.

After the etch process is completed, the photoresist above the conductive layer is removed.

Since the dielectric layer is non-conductive, after the etch process, the dielectric layer and the conductive layer outside a region corresponding to the capacitor together form the salicide block layer, and the dielectric layer and the conductive layer in the region corresponding to the capacitor respectively serve as the dielectric layer and the upper electrode plate of the capacitor.

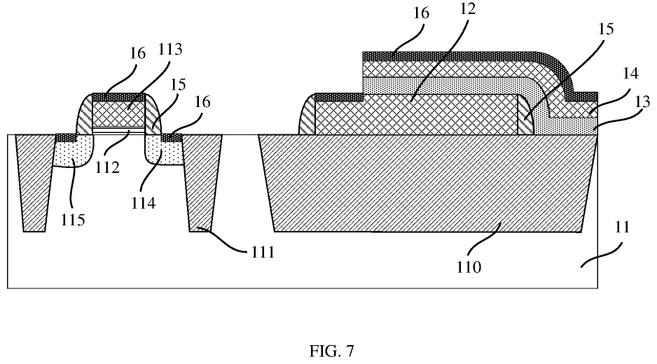

Referring to FIG. 6, the dielectric layer 13 and the upper electrode plate 14 of the capacitor are formed after the etch process; the dielectric layer 13 of the capacitor covers a portion of the surface of the lower electrode plate 12 of the capacitor, and the upper electrode plate 14 of the capacitor completely covers the dielectric layer 13 of the capacitor; the dielectric layer 13 of the capacitor extends from the surface of the lower electrode plate 12 to the surface of the substrate 11, and the dielectric layer 13 is on the field oxide layer 110; and the dielectric layer 13 of the capacitor covers the sidewall 15 on one side of the lower electrode plate 12.

In step 211, a layer of metal is formed on the substrate by means of sputtering, and rapid thermal anneal process is performed to form the salicides.

A layer of metal, such as Ti, Co, or Ni, is formed on the substrate by means of sputtering; then, rapid thermal anneal process is performed, such that the metal layer formed by means of sputtering reacts with the polysilicon below the metal layer to form the salicides.

Due to the existence of the salicide block layer, the salicides are formed on the top of the polysilicon not covered with the salicide block layer, and the salicides are not formed on the top of the polysilicon covered with the salicide block layer.

If the material of the conductive layer is polysilicon, since the salicide block layer is comprised of the stacked dielectric layer and polysilicon layer, during the formation process of the salicides, the salicides are also formed on the top of the polysilicon layer above the dielectric layer; and similarly, since the material of the upper electrode plate of the capacitor is polysilicon and the material of the lower electrode plate is polysilicon, the salicides are also formed on the top of the upper electrode plate and the exposed top of the lower electrode plate of the capacitor.

If the material of the conductive layer is a conductive material other than polysilicon, since a layer of metal is also sputtered on the surface of the conductive layer above the dielectric layer, during the formation process of the salicides, but the sputtered metal and the conductive layer do not form a salicide, the sputtered metal is remained, such that the sputtered metal and the original conductive layer together form a conductive layer.

In one example, the material of the conductive layer is polysilicon, referring to FIG. 7, the salicide 16 is formed on the top of the gate 113, the source region 115, and the drain region 114 of the CMOS device, and the salicide 16 is also formed on the top of the upper electrode plate 14 of the capacitor and on the exposed top of the lower electrode plate 12 of the capacitor.

In step 212, an interlayer dielectric layer is formed.

The interlayer dielectric layer is deposited on the substrate.

In step 213, contacts are formed in the interlayer dielectric layer, wherein the upper electrode plate and the lower electrode plate of the capacitor are led out from the contacts.

A photolithography process and an etching process are performed to form the contacts in the interlayer dielectric layer. The gate, the source region, and the drain region of the CMOS device respectively correspond to the contacts, and the upper electrode plate and the lower electrode plate of the capacitor respectively correspond to the contacts, wherein the upper electrode plate and the lower electrode plate of the capacitor, and the gate, the source region, and the drain region of the CMOS device are led out from the contacts.

The benefit of this technique includes: by changing the material of the salicide barrier layer, the manufacture of the salicide block layer is combined with the manufacture of the upper electrode plate and the dielectric layer of the capacitor, eliminating the separate photolithography and etch processes for manufacturing the capacitor, effectively reducing the manufacture cost of an integrated capacitor and facilitating implementation of low-cost capacitor manufacture.

Obviously, the foregoing embodiments are merely for clear description of made examples, and are not limitations on the implementations. For those of ordinary skill in the art, other different forms of changes or modifications can be made on the basis of the above description. There is no need and cannot be exhaustive for all implementations. And, the obvious changes or modifications introduced thereby are still within the protection scope of this application.

What is claimed is:

1. A method for manufacturing a capacitor, comprising:
forming a polysilicon layer on a substrate;
forming a polysilicon structure by etching the polysilicon layer, wherein the polysilicon structure comprises a lower electrode plate of the capacitor;
forming sidewalls on two sides of the polysilicon structure;
depositing a dielectric layer and a conductive layer sequentially;
performing a photolithography process to define salicide block layer patterns and upper electrode plate patterns of the capacitor;
forming a salicide block layer, and an upper electrode plate and a dielectric layer of the capacitor, by sequentially etching the conductive layer and the dielectric layer, according to the salicide block layer patterns and the upper electrode plate patterns of the capacitor; and
forming salicides.

2. The method for manufacturing a capacitor, according to claim 1, wherein forming a polysilicon structure by etching the polysilicon layer, further comprising:
performing a photolithography process to define a gate of a CMOS device and the lower electrode plate of the capacitor; and
forming the polysilicon structure by etching the polysilicon layer, wherein the polysilicon structure comprises the gate of the CMOS device and the lower electrode plate of the capacitor.

3. The method for manufacturing a capacitor, according to claim 1, wherein the dielectric layer of the capacitor covers a portion of the surface of the lower electrode plate of the capacitor, and the upper electrode plate of the capacitor completely covers the dielectric layer of the capacitor.

4. The method for manufacturing a capacitor, according to claim 2, wherein the forming sidewalls on two sides of the polysilicon structure, further comprising:
performing a lightly doped drain implantation process of the CMOS device; and
forming the sidewalls on two sides of the gate of the CMOS device and on two sides of the lower electrode plate of the capacitor.

5. The method for manufacturing a capacitor, according to claim 2, wherein before depositing a dielectric layer and a conductive layer sequentially, the method further comprising:
forming a source region and a drain region of the CMOS device.

6. The method for manufacturing a capacitor, according to claim 1, wherein before the forming a polysilicon layer on a substrate, the method further comprising:
forming active regions in the substrate, and forming field oxide layers in regions outside the active regions.

7. The method for manufacturing a capacitor, according to claim 4, wherein the forming salicides, further comprising:
forming a layer of metal on the substrate by sputtering, and forming the salicides via a rapid thermal anneal process.

8. The method for manufacturing a capacitor, according to claim 1, wherein the method further comprising:
forming an interlayer dielectric layer; and
forming contacts in the interlayer dielectric layer, wherein the upper electrode plate and the lower electrode plate of the capacitor are led out from the contacts.
